(19) United States
(12) Patent Application Publication
(10) Pub. No.: US 2026/0344539 A1
(43) Pub. Date: Oct. 29, 2026

(54) THREE-DIMENSIONAL PACKAGE STRUCTURE

(71) Applicant: Winbond Electronics Corp., Taichung City (TW)

(72) Inventors: Fu Tsai Hou, HsinChu (TW); San-Ha Park, Hsinchu (TW); I-Chun Tseng, Hsinchu County (TW)

(73) Assignee: Winbond Electronics Corp., Taichung City (TW)

(21) Appl. No.: 19/655,681

(22) Filed: Apr. 22, 2026

(30) Foreign Application Priority Data
Apr. 28, 2025 (TW) 114115873

(51) Int. Cl. H10W 90/28; H10B 80/00; H10W 20/20; H10W 70/63; H10W 72/00; H10W 74/15; H10W 90/00

(52) U.S. Cl. CPC H10W 90/28; H10B 80/00; H10W 20/211; H10W 70/635; H10W 72/856; H10W 74/15; H10W 90/722; H10W 90/724; H10W 90/7295

(57) ABSTRACT

Provided is a three-dimensional (3D) package structure. The 3D package structure includes a motherboard, an interposer, a memory stack structure and a system-on-chip. The interposer is disposed on the motherboard and is electrically connected to the motherboard via a plurality of first connection elements. The memory stack structure is disposed on the interposer and is electrically connected to the interposer via a plurality of second connection elements, wherein the memory stack structure includes a plurality of memory chips stacked and electrically connected to each other. The system-on-chip is disposed on the memory stack structure and is electrically connected to the memory stack structure via a plurality of third connection elements.

### CROSS-REFERENCE TO RELATED APPLICATION

This application claims the priority benefit of Taiwan application serial no. 114115873, filed on Apr. 28, 2025. The entirety of the above-mentioned patent application is hereby incorporated by reference herein and made a part of this specification.

### BACKGROUND

### Technical Field

The present invention relates to a semiconductor package structure, and more particularly to a three-dimensional (3D) package structure with a memory stack structure suitable for high bandwidth applications.

### Description of Related Art

As the demand for artificial intelligence grows, in order to reduce manufacturing costs and adapt to high bandwidth applications, using a stacked package structure to manufacture a memory has become increasingly popular. For example, a conventional high bandwidth memory stacked package structure includes a memory chip package, other types of chips, an interposer and a package substrate. The memory chip package includes a base chip and a plurality of memory chips stacked on the base chip. The other types of chips, such as logic chips, etc., are disposed on the interposer adjacent to the memory chip package in the horizontal direction and are electrically connected to the interposer. In this way, in order to meet the high bandwidth requirement, the conventional high bandwidth memory is limited in the area miniaturization, and thus the packaging substrate must be provided to carry and electrically connected with the interposer on which the memory chip package and various other chips are disposed to prevent the high bandwidth memory from warping. In other words, the interposer must be disposed on one side of the package substrate and electrically connected to the motherboard through the package substrate via solder balls located on the other side of the package substrate.

For the stacked package structure, since the memory chip package, the interposer and the package substrate need to be disposed and thus the thickness is relatively large, so the conventional high bandwidth memory is limited in thickness miniaturization. The high bandwidth memory limited by the thickness miniaturization is not conducive to the improvement of some applications, such as the edge computing application. In addition, since the package substrate includes an expensive organic material substrate, the cost cannot be reduced. Furthermore, since the package substrate including the organic material substrate is located between the interposer and the motherboard, the stacked package structure must be heat-dissipated through the top, resulting in lower heat-dissipation performance of the stacked package structure.

### SUMMARY

The present invention provides a 3D package structure, wherein the interposer is connected to the motherboard via the connection element without disposing a package substrate therebetween.

The 3D package structure of the present invention includes a motherboard, an interposer, a memory stack structure and a system-on-chip. The interposer is disposed on the motherboard and is electrically connected to the motherboard via a plurality of first connection elements. The memory stack structure is disposed on the interposer and is electrically connected to the interposer via a plurality of second connection elements, wherein the memory stack structure includes a plurality of memory chips stacked and electrically connected to each other. The system-on-chip is disposed on the memory stack structure and is electrically connected to the memory stack structure via a plurality of third connection elements.

The 3D package structure of the present invention includes an interposer, a memory stack structure and a system-on-chip. The interposer comprises a plurality of first connection elements configured to connect to a motherboard. The memory stack structure is disposed on the interposer and is electrically connected to the interposer via a plurality of second connection elements, wherein the memory stack structure includes a plurality of memory chips stacked and electrically connected to each other. The system-on-chip is disposed on the memory stack structure and is electrically connected to the memory stack structure via a plurality of third connection elements.

Based on the above, in the 3D package structure of the present invention, the system-on-chip is disposed on and electrically connected to the memory stack structure, the memory stack structure is disposed on and electrically connected to the interposer, and the interposer is disposed on and electrically connected to the motherboard via the first connection element. Compared with the 3D package structure in the prior art, in the 3D package structure of the present invention, the organic material substrate between the interposer and the motherboard is omitted. Therefore, the 3D package structure of the present invention may have a smaller thickness and is beneficial to the edge computing application, and has a lower manufacturing cost and better heat-dissipation performance.

### BRIEF DESCRIPTION OF THE DRAWINGS

FIG. 1 is a schematic cross-sectional view of the 3D package structure of the first embodiment of the present invention.

FIG. 2 is a schematic cross-sectional view of the 3D package structure of the second embodiment of the present invention.

### DESCRIPTION OF THE EMBODIMENTS

In each embodiment of the present invention, a memory stack structure formed by a plurality of memory chips is disposed on an interposer and electrically connected to the interposer, and the interposer on which the memory stack structure is disposed is disposed on a motherboard and connected to the motherboard via a connection element. That is, in each embodiment of the present invention, no package substrate is disposed between the interposer and the motherboard, thereby effectively reducing the thickness and manufacturing cost of the package structure, facilitating the edge computing application, and improving the heat-dissipation performance of the package structure. Each embodiment of the present invention will be described in detail below.

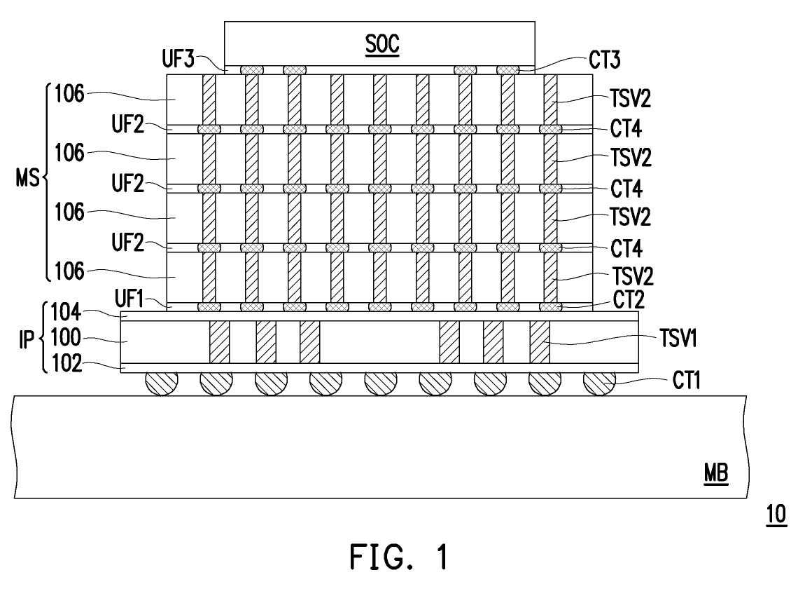

Referring to FIG. 1, the 3D package structure 10 of the present embodiment includes a motherboard MB, an interposer IP, a memory stack structure MS and a system-on-chip SOC. The interposer IP is disposed on the motherboard MB and is electrically connected to the motherboard MB. The memory stack structure MS is disposed on the interposer IP and is electrically connected to the interposer IP. The system-on-chip SOC is disposed on the memory stack structure MS and is electrically connected to the memory stack structure MS.

The motherboard MB is used to carry the interposer IP, the memory stack structure MS and the system-on-chip SOC. In addition, the motherboard MB may include a circuit pattern (not shown) so that the interposer IP, the memory stack structure MS and the system-on-chip SOC may be electrically connected to the motherboard MB via various connection elements. In the present embodiment, the motherboard MB may be a motherboard well known in the art, and the present invention does not limit this.

In the present embodiment, the interposer IP includes a silicon substrate 100, a lower redistribution layer (RDL) 102, an upper RDL 104 and a plurality of through silicon vias TSV1. The lower RDL 102 and the upper RDL 104 are disposed on the lower surface and the upper surface of the silicon substrate 100, respectively, and the through silicon vias TSV1 are disposed in the silicon substrate 100 and penetrate through the silicon substrate 100 to connect the lower RDL 102 and the upper RDL 104. In this way, the upper RDL 104 may be electrically connected to the lower RDL 102 via the through silicon vias TSV1. Since the main material of the interposer IP is silicon (the thermal conductivity coefficient is about 148 W/(m×K)), the interposer IP may exhibit good thermal conductivity.

Furthermore, in the present embodiment, the interposer IP is connected to the motherboard MB via a plurality of first connection elements CT1. In detail, the first connection elements CT1 are disposed between the interposer IP and the motherboard MB and connected to the lower RDL 102 of the interposer IP and the circuit pattern of the motherboard MB, so that the interposer IP may be electrically connected to the motherboard MB via the first connection elements CT1. The first connection element CT1 is, for example, the solder ball, and may have a diameter not less than 0.3 mm, so that the interposer IP may be firmly attached to the motherboard MB. In FIG. 1, the number and the layout of the first connection elements CT1 are merely exemplary, and the present invention does not limit this.

In the present embodiment, the memory stack structure MS includes four memory chips 106 stacked and electrically connected to each other to include more than 4000 input/output terminals, but the present invention is not limited thereto. In other embodiments, the memory stack structure MS may include more or less memory chips 106 depending on actual needs. The memory chips 106 in the memory stack structure MS may be the same as or different from each other. The memory chip 106 may be a dynamic random access memory chip, but the present invention is not limited thereto. Each memory chip 106 includes a plurality of through silicon vias TSV2. The through silicon vias TSV2 penetrate through the memory chip 106. In addition, the through silicon vias TSV2 in two adjacent memory chips 106 are electrically connected to each other via a plurality of fourth connection elements CT4 to transmit electrical signals in the memory stack structure MS.

In addition, when the through silicon vias TSV2 connected in series via the fourth connection elements CT4 are grounded, these through silicon vias TSV2 are not used to transmit electrical signals, but only used as heat-dissipation paths for transferring heat energy. Through the circuit design, a portion of the through silicon vias TSV2 in the memory chip 106 may be used to transmit electrical signals to the interposer IP and the motherboard MB, and the remaining through silicon vias TSV2 may be used to transmit heat energy to the outside through the interposer IP and the motherboard MB. In the present embodiment, the through silicon vias TSV2 located in the central region of the memory chip 106 may be used as the heat-dissipation paths, but the present invention is not limited thereto.

In the present embodiment, the fourth connection element CT4 may be a micro-bump, but the present invention is not limited thereto. In other embodiments, depending on actual circumstances, the fourth connection element CT4 may be a hybrid bump. In FIG. 1 , the number and the layout of the fourth connection elements CT4 are merely exemplary, and the present invention does not limit this. In addition, an underfill UF2 may be disposed between adjacent memory chips 106 and encapsulate the fourth connection elements CT4 to protect the fourth connection elements CT4.

The memory stack structure MS is connected to the interposer IP via a plurality of second connection elements CT2. In detail, the second connection elements CT2 are disposed between the memory stack structure MS and the interposer IP, and are connected to the upper RDL 104 of the interposer IP and the through silicon vias TSV2 of the bottom memory chip 106 in the memory stack structure MS, so that the memory stack structure MS may be electrically connected to the interposer IP via the second connection elements CT2, and heat energy may also be transferred to the outside through the interposer IP and the motherboard MB.

In the present embodiment, the second connection element CT2 may be a micro-bump, but the present invention is not limited thereto. In other embodiments, depending on actual circumstances, the second connection element CT2 may be a hybrid bump. In FIG. 1, the number and the layout of the second connection elements CT2 are merely exemplary, and the present invention does not limit this. In addition, an underfill UF1 may be disposed between the upper RDL 104 of the interposer IP and the bottom memory chip 106 in the memory stack structure MS and encapsulate the second connection elements CT2 to protect the second connection elements CT2.

The system-on-chip SOC is electrically connected to the memory stack structure MS via a plurality of third connection elements CT3. In detail, the third connection elements CT3 are disposed between the system-on-chip SOC and the memory stack structure MS, and are connected to pads (not shown) of the system-on-chip SOC and the through silicon vias TSV2 of the top memory chip 106 in the memory stack structure MS, so that the system-on-chip SOC may be electrically connected to the memory stack structure MS via the third connection elements CT3. The system-on-chip SOC may be a logic chip, a central processing unit (CPU) chip, a graphic processing unit (GPU) chip, a digital signal processing (DSP) chip, an application specific integrated circuit (ASIC) chip, etc., but the present invention is not limited thereto.

In the present embodiment, the third connection element CT3 may be a micro-bump, but the present invention is not limited thereto. In other embodiments, depending on actual circumstances, the third connection element CT3 may be a hybrid bump. In FIG. 1 , the number and the layout of the third connection elements CT3 are merely exemplary, and the present invention does not limit this. In addition, an underfill UF3 may be disposed between the system-on-chip SOC and the top memory chip 106 in the memory stack structure MS and encapsulate the third connection elements CT3 to protect the third connection elements CT3.

In the 3D package structure 10 of the present embodiment, the system-on-chip SOC is disposed on and electrically connected to the memory stack structure MS, the memory stack structure MS is disposed on and electrically connected to the interposer IP, and the interposer IP is connected to the motherboard MB via the first connection elements CT1. Therefore, compared with the 3D package structure in the prior art, the organic material substrate between the interposer IP and the motherboard MB is omitted. In this way, the thickness of the package structure is effectively reduced, which is beneficial to the edge computing application and reduces manufacturing costs.

In addition, in the 3D package structure 10 of the present embodiment, the interposer IP having good thermal conductivity performance is directly connected to the motherboard MB via the first connection elements CT1, and the organic material substrate having poor thermal conductivity performance (thermal conductivity coefficient is about 0.3 W/(m×K)) is omitted. In this way, compared with the 3D package structure in the prior art, the 3D package structure 10 may have better heat-dissipation performance.

In the 3D package structure 10 of the present embodiment, the orthographic projection area of the system-on-chip SOC on the motherboard MB is smaller than the orthographic projection area of the memory stack structure MS on the motherboard MB. That is, during the manufacturing process of the 3D package structure 10, the system-on-chip SOC is formed on the memory stack structure MS in a chip-on-wafer manner, but the present invention is not limited thereto. In other embodiments, depending on actual needs, the system-on-chip SOC may be formed on the memory stack structure MS in a wafer-on-wafer manner.

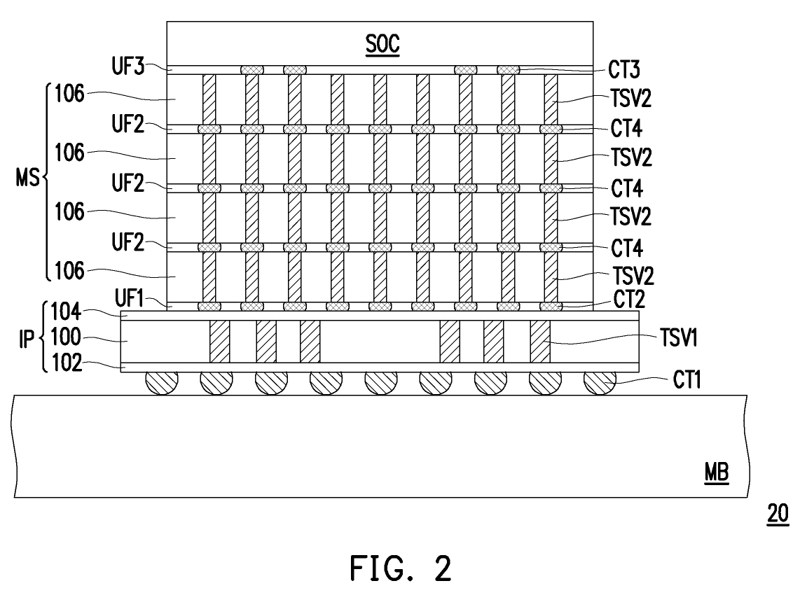

FIG. 2 is a schematic cross-sectional view of the 3D package structure of the second embodiment of the present invention. In the present embodiment, the same devices as those in the first embodiment will be denoted by the same reference symbols and the description thereof will not be repeated.

Referring to FIG. 2, in the 3D package structure 20 of the present embodiment, the system-on-chip SOC may be formed on the memory stack structure MS in a wafer-to-wafer manner. In this way, the edge of the system-on-chip SOC may be aligned with the edge of the memory stack structure MS.

Based on the above, the 3D package structures of the present embodiments may have lower manufacturing cost and energy consumption, thereby reducing carbon emissions in the package manufacturing process. Therefore, the present invention provides a green semiconductor technology.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A three-dimensional (3D) package structure, comprising:
a motherboard;
an interposer, disposed on the motherboard and electrically connected to the motherboard via a plurality of first connection elements;
a memory stack structure, disposed on the interposer and electrically connected to the interposer via a plurality of second connection elements, wherein the memory stack structure comprises a plurality of memory chips stacked and electrically connected to each other; and
a system-on-chip, disposed on the memory stack structure and electrically connected to the memory stack structure via a plurality of third connection elements.

2. The 3D package structure of claim 1, wherein the interposer comprises:
a silicon substrate;
an upper redistribution layer (RDL), disposed on an upper surface of the silicon substrate to be connected to the plurality of second connection elements;
a lower RDL, disposed on a lower surface of the silicon substrate to be connected to the plurality of first connection elements; and
a plurality of through silicon vias, disposed in the silicon substrate to connect the upper RDL and the lower RDL.

3. The 3D package structure of claim 1, wherein the memory chip comprises a plurality of through silicon vias, and the through silicon vias in two adjacent memory chips are electrically connected to each other via a plurality of fourth connection elements.

4. The 3D package structure of claim 3, wherein the fourth connection element comprises a micro-bump or a hybrid bump.

5. The 3D package structure of claim 3, further comprising an underfill encapsulating the plurality of fourth connection elements.

6. The 3D package structure of claim 3, wherein a portion of the plurality of through silicon vias are electrically connected to the interposer to transmit electrical signals, and the rest of the plurality of through silicon vias are grounded to transmit heat energy.

7. The 3D package structure of claim 1, wherein the first connection element comprises a solder ball.

8. The 3D package structure of claim 1, wherein the second connection element comprises a micro-bump or a hybrid bump.

9. The 3D package structure of claim 1, wherein the third connection element comprises a micro-bump or a hybrid bump.

10. The 3D package structure of claim 1, wherein the memory chip comprises a dynamic random access memory chip.

11. The 3D package structure of claim 1, further comprising an underfill encapsulating the plurality of third connection elements.

12. The 3D package structure of claim 1, further comprising an underfill encapsulating the plurality of second connection elements.

13. The 3D package structure of claim 1, wherein the memory stack structure comprises more than 4000 input/output terminals.

14. The 3D package structure of claim 1, wherein an orthographic projection area of the system-on-chip on the motherboard is smaller than an orthographic projection area of the memory stack structure on the motherboard.

15. The 3D package structure of claim 1, wherein an edge of the system-on-chip is aligned with an edge of the memory stack structure.

16. A three-dimensional (3D) package structure, comprising:
an interposer, comprising a plurality of first connection elements configured to connect to a motherboard;
a memory stack structure, disposed on the interposer and electrically connected to the interposer via a plurality of second connection elements, wherein the memory stack structure comprises a plurality of memory chips stacked and electrically connected to each other; and
a system-on-chip, disposed on the memory stack structure and electrically connected to the memory stack structure via a plurality of third connection elements.

17. The 3D package structure of claim 16, wherein the interposer comprises:
a silicon substrate;
an upper redistribution layer (RDL), disposed on an upper surface of the silicon substrate to be connected to the plurality of second connection elements;
a lower RDL, disposed on a lower surface of the silicon substrate to be connected to the plurality of first connection elements; and
a plurality of through silicon vias, disposed in the silicon substrate to connect the upper RDL and the lower RDL.

18. The 3D package structure of claim 16, wherein the memory chip comprises a plurality of through silicon vias, and the through silicon vias in two adjacent memory chips are electrically connected to each other via a plurality of fourth connection elements.

19. The 3D package structure of claim 18, wherein the fourth connection element comprises a micro-bump or a hybrid bump.

20. The 3D package structure of claim 18, further comprising an underfill encapsulating the plurality of fourth connection elements.
